(19) United States
(12) Patent Application Publication
(10) Pub. No.: US 2001/0021414 A1
(43) Pub. Date: Sep. 13, 2001

(54) CVD method

(76) Inventors: Masato Morishima, Nirasaki-shi (JP); Yasuhiro Oshima, Nirasaki-shi (JP)

Correspondence Address: Smith, Gambrell & Russell, LLP, Beveridge, DeGrandi, Weilacher & Young, Intellectual Property Group, 1850 M Street, N.W. (Suite 800), Washington, DC, 20036, US

(21) Appl. No.: 09/799,531

(22) Filed: Mar. 7, 2001

(30) Foreign Application Priority Data
Mar. 7, 2000 (JP) 2000-61705

(51) Int. Cl. C23C 16/00

(52) U.S. Cl. 427/248.1

(57) ABSTRACT

There is provided a CVD method capable of inexpensively and effectively preventing films from being peeled off from the inner wall of a chamber and/or members in the chamber. By supplying a passivating gas into a chamber 11 while no object to be processed exists in the chamber 11, a passivation film is formed the inner wall of the chamber 11 and/or the surface of a member 20 in the chamber 11. Subsequently, by supplying a pre-coating gas into the chamber 11 while no object to be processed exists in the chamber, a pre-coat film is formed on the surface of the passivation film. Thereafter, an object W to be processed is introduced into the chamber 11, and a depositing gas is supplied into the chamber 11 to carry out a deposition process on the object W.

### BACKGROUND OF THE INVENTION

1. Field of The Invention

The present invention relates generally to a CVD method for supplying a deposition gas into a chamber to deposit a thin film on an object to be processed.

2. Description of Related Background Art

In a semiconductor producing process, a metal such as Ti, Al or Cu, or a metal compound such as WSi, TiN or TiSi is deposited to form a thin film in order to fill the thin film in a hole between wiring layers which are formed in a semiconductor wafer serving as an object to be processed (which will be hereinafter referred to as a wafer) or in order to cause the thin film to serve as a barrier layer.

Conventionally, the thin films of these metals and metal compounds are deposited by the physical vapor deposition (PVD). In recent years, the scale down and high density integration of devices are particularly required, and design rules are particularly severely restricted, so that it is difficult to obtain sufficient characteristics by the PVD having bad filing characteristics. Therefore, such thin films are deposited by the chemical vapor deposition (CVD) which can be expected to form higher quality films.

For example, when a Ti thin-film is deposited by the CVD, TiCl₄ is used as a deposition gas, and H₂ is used as a reducing gas and Ar is used as a plasma stabilizing. Such gases are used first for carrying out a pre-coat process, and then, for carrying out a main deposition process. After such a deposition process, a cleaning process is carried out with, e.g., ClF₃ gas, periodically or if necessary.

However, in such a deposition of the Ti thin-film, there is a problem in that the thin-film formed on the surface of a gas supplying shower head, which is arranged in a chamber, is peeled off during the pre-coat process. Such a problem considers to be related with a bad adherence between the surface of the shower head and the thin-film formed on the surface of the gas supplying shower head. Such a problem is not only caused in the shower head, but there is some possibility that the problem is caused in other members in the chamber. There is also some possibility that the problem is caused during the CVD process using other materials.

### SUMMARY OF THE INVENTION

It is therefore an object of the present invention to eliminate the aforementioned problems and to provide a CVD method capable of inexpensively and effectively preventing a thin-film from being peeled off from the inner wall of a chamber and/or a member in the chamber.

The inventors examined such peeling of films during a pre-coat process, and confirmed that the peeling of films was caused when a new shower head or a chemically cleaned (chemically polished) shower head was introduced into the system and that the peeling of films was not caused after the system was cleaned with ClF₃ once. After further studying on the basis of this fact, it was found that it was possible to form a passivation film on the inner wall of the chamber and/or the surface of the member in the chamber by supplying a predetermined gas into the chamber, so that it was possible to prevent films, which were easily peeled off during a pre-coat process, from being formed by the passivation film. For example, if a fluorine containing gas is supplied to previously form a passivation film of, e.g., a metal fluoride or a metal chloride, on the inner wall of the chamber and/or the surface of the member in the chamber, a strong film which is difficult to be peeled off during the pre-coat process, and/or a gaseous fluoride is formed, and any films which are easily peeled off are not formed.

The present invention has been made on the basis of such knowledge. According to a first aspect of the present invention, there is provided a chemical vapor deposition method comprising the steps of: supplying a passivating gas into a chamber, in which a chemical vapor deposition is carried out, while no object to be processed exists in the chamber, to form a passivation film on at least one of the inner wall of the chamber and the surface of a member in the chamber; subsequently supplying a pre-coating gas into the chamber while no object to be processed exists in the chamber, to form a pre-coat film on the surface of the passivation film; introducing an object to be processed, into the chamber; and supplying a depositing gas into the chamber to carry out a deposition process on the object.

According to a second aspect of the present invention, there is provided a chemical vapor deposition method comprising the steps of: supplying a passivating gas into a chamber, in which a chemical vapor deposition is carried out, while no object to be processed exists in the chamber, to form a passivation film on at least one of the inner wall of the chamber and the surface of a member in the chamber; subsequently supplying a pre-coating gas into the chamber while no object to be processed exists in the chamber, and producing a first plasma, to form a pre-coat film on the surface of the passivation film; introducing an object to be processed, into the chamber; and supplying a depositing gas into the chamber and producing a second plasma to carry out a deposition process on the object.

According to a third aspect of the present invention, there is provided a chemical vapor deposition method comprising the steps of: supplying a fluorine containing gas into a chamber, in which a chemical vapor deposition is carried out, while no object to be processed exists in the chamber, to previously form a passivation film of a metal fluoride on at least one of the inner wall of the chamber and the surface of a member in the chamber; subsequently supplying a depositing gas into the chamber while no object to be processed exists in the chamber, to form a pre-coat film on the surface of the passivation film; introducing an object to be processed, into the chamber; and supplying a depositing gas into the chamber to carry out a deposition process on the object.

According to a fourth aspect of the present invention, there is provided a chemical vapor deposition method comprising the steps of: supplying a fluorine containing gas into a chamber, in which a chemical vapor deposition is carried out, while no object to be processed exists in the chamber, to previously form a passivation film of a metal fluoride on at least one of the inner wall of the chamber and the surface of a member in the chamber; subsequently supplying a depositing gas into the chamber while no object to be processed exists in the chamber, and producing a first plasma, to form a pre-coat film on the surface of the passivation film; introducing an object to be processed, into the chamber; and supplying a depositing gas into the chamber and producing a second plasma to carry out a deposition process on the object.

According to a fifth aspect of the present invention, there is provided a chemical vapor deposition method for carrying out a deposition process using a chemical vapor deposition system comprising a chamber for carrying out a chemical vapor deposition, a deposition gas supply system for supplying a deposition gas into the chamber, and a cleaning gas supply system for supplying a fluorine containing gas into the chamber as a cleaning gas for cleaning after deposition, the method comprising the steps of: supplying the fluorine containing gas serving as the cleaning gas into the chamber while no object to be processed exists in the chamber, to form a passivation film of a metal fluoride on at least one of the inner wall of the chamber and the surface of a member in the chamber; subsequently supplying a depositing gas from the deposition gas supply system into the chamber while no object to be processed exists in the chamber, to form a pre-coat film on the surface of the passivation film; introducing an object to be processed, into the chamber; and supplying a depositing gas from the deposition gas supply system into the chamber to carry out a deposition process on the object.

According to the present invention, it is possible to form a desired passivation film, which prevents films from being peeled off during a pre-coat process, on the inner wall of the chamber and/or the surfaces of the members in the chamber, with a simple method for introducing a passivating gas into the chamber in which an object to be processed does not exist. Therefore, it is possible to effectively and inexpensively prevent films from being peeled off from the inner wall of the chamber and the members in the chamber.

For example, as the third and fourth aspect of the present invention, when a passivation film of a fluoride is formed on the inner wall of the chamber and/or the surfaces of the members in the chamber by supplying a fluorine containing gas into the chamber, even if the passivation film of the fluoride reacts with a deposition gas which will be subsequently supplied, reaction products can be discharged as gaseous components, and it is possible to prevent films from being peeled off, so that it is possible to prevent peeled films from having a bad influence on the process.

As the fifth aspect of the present invention, if the CVD system has a cleaning gas supply system for supplying a fluorine containing gas, e.g., ClF₃, as a cleaning gas, the cleaning gas has only to be introduced from the cleaning gas supply system, which is originally provided in the CVD system, into the chamber at a predetermined temperature, so that it is possible to very easily form a passivation film on the inner wall of the chamber and/or the surfaces of the members in the chamber.

### BRIEF DESCRIPTION OF THE DRAWINGS

The present invention will be understood more fully from the detailed description given herebelow and from the accompanying drawings of the preferred embodiments of the invention. However, the drawings are not intended to imply limitation of the invention to a specific embodiment, but are for explanation and understanding only.

In the drawings:

FIG. 1 is a sectional view showing an example of a CVD system used for carrying out the present invention;

FIG. 2 is a chart showing an EDAX measurement profile on the surface of an NC-Ni sample during the cycle tests for TiCl₄ and ClF₃ processes;

FIG. 3 is a chart showing an EDAX measurement profile on the surface of a C22 sample during the cycle tests for TiCl₄ and ClF₃ processes;

FIG. 4 is a graph showing Gibbs free energies of chlorides and fluorides concerning TiCl₄ and ClF₃ processes;

FIG. 5 is a sectional view schematically showing the surface state of an NC-Ni sample during each of TiCl₄ and ClF₃ processes in the cycle tests for the respective processes;

FIG. 6 is a sectional view schematically showing the surface state of a C22 sample during each of TiCl₄ and ClF₃ processes in the cycle tests for the respective processes; and

FIG. 7 is a flow chart for explaining a preferred embodiment of a CVD process according to the present invention.

### DESCRIPTION OF THE PREFERRED EMBODIMENTS

Referring now to the accompanying drawings, a preferred embodiment of the present invention will be described below.

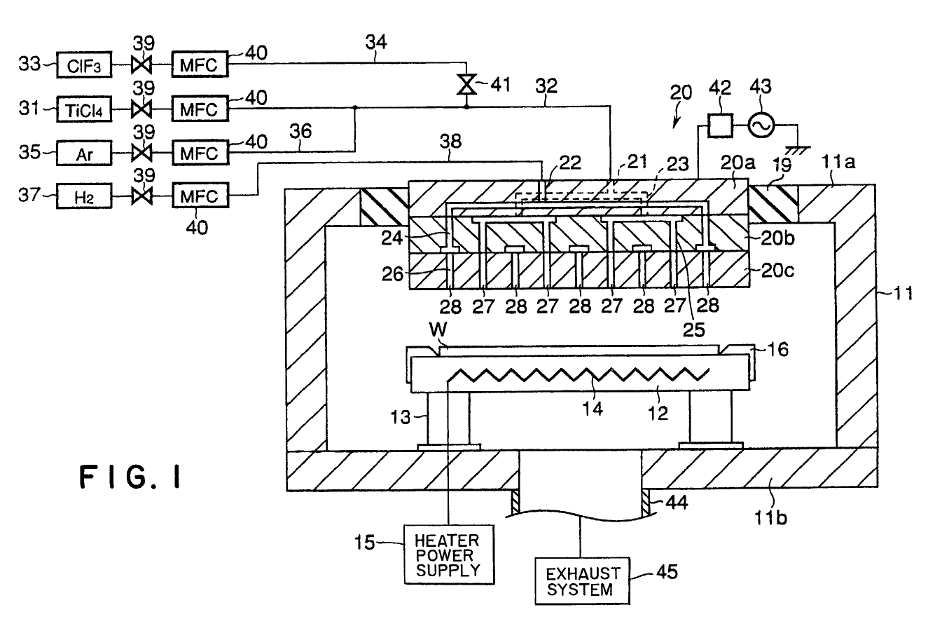

First, with respect to the circumstances of the present invention, an example of a process for depositing a Ti thin-film by the CVD will be described below. FIG. 1 is a sectional view showing an example of a CVD system. This deposition system has a substantially cylindrical airtight chamber 11, in which a susceptor 12 for horizontally supporting a semiconductor wafer W serving as an object to be processed is supported on a cylindrical supporting member 13. On the outer peripheral portion of the susceptor 12, a guide ring 16 for guiding the semiconductor wafer is provided. In the susceptor 12, a heater 14 is embedded. The heater 14 is fed by a power supply 15 to heat the semiconductor wafer W to a predetermined temperature.

On the ceiling wall 11a of the chamber 11, a shower head 20 is provided via an insulating member 19. The shower head 20 comprises an top-stage block body 20a, a middle-stage block body 20b and a bottom-stage block body 20c. In the top face of the top-stage block body 20a, a first inlet 21 for introducing TiCl₄, and a second inlet 22 for introducing H₂ serving as a reducing gas are formed. In the top-stage block body 20a, a plurality of TiCl₄ passages 23 branch from the first inlet 21. The TiCl₄ passages 23 are communicated with TiCl₄ passages 25, which are formed in the middle-stage block body 20b, to be communicated with TiCl₄ discharging holes 27 which are formed in the bottom-stage block body 20c. In the top-stage block body 20a, a plurality of H₂ passages 24 branch from the second inlet 22. The H₂ passages 24 are communicated with H₂ passages 26, which are formed in the middle-stage block body 20b, to be communicated with H₂ discharging holes 28 which are formed in the bottom-stage block body 20c. That is, the shower head 20 is a matrix type shower head for separately supplying TiCl₄ and H₂ into the chamber 11, so that TiCl₄ and H₂ are mixed to cause a plasma reaction after being discharged from the shower head 20.

The first inlet 21 is connected to a line 32 which extends from a TiCl₄ source 31. The line 32 is connected to a line 36, which extends from an Ar source 35 for supplying Ar serving as a carrier gas, so that TiCl₄ gas supplied from the TiCl₄ source 31 is carried on Ar gas, which is supplied via the line 36, to be supplied into the chamber 11 via the line 32. The line 32 is connected to a line 34, which extends from a ClF₃ source 33 for supplying ClF₃ serving as a cleaning gas, so that ClF₃ can be supplied into the chamber 11 via the lines 34 and 32. The second inlet is connected to a line 38, which extends from an H₂ source 37, so that H₂ gas supplied from the H₂ source 37 is supplied into the chamber 11 via the line 38. Each of the lines 32, 34, 36 and 38 extending from the respective gas sources is provided with a valve 39 and a mass flow controller 40. The line 34 is provided a switching valve 41 in the vicinity of the connecting portion of the line 32. A line (not shown) for supplying N₂ gas into the chamber 11 is also provided.

The shower head 20 is connected to a high-frequency power supply 43 via a matching unit 42. By supplying a high-frequency power from the high-frequency power supply 43 to the shower head 20, the plasma of the gasses supplied into the chamber 11 via the shower head 20 is produced, so that a deposition reaction proceeds.

The bottom wall 11b of the chamber 11 is connected to an exhaust pipe 44 which is connected to an exhaust system 45. By operating the exhaust system 45, the pressure in the chamber 11 can be reduced to a predetermined degree of vacuum.

In order to deposit a Ti thin-film on the semiconductor wafer W by means of such a system, while the interior of the chamber 11 is heated to a predetermined temperature by means of the heater 14, the interior of the chamber 11 is first evacuated by means of the exhaust system 45. Subsequently, TiCl₄ gas and Ar gas and H₂ gas are introduced into the chamber 11 at predetermined flow rates so that the pressure in the chamber 11 is a predetermined pressure, and a high-frequency power is supplied from the high-frequency power supply 43 to the shower head 20 to produce plasma in the chamber 11 and to carry out a pre-coat process on the inner wall of the chamber 11 and the surfaces of members in the chamber 11, such as the shower head 20 arranged in the chamber 11.

Thereafter, the semiconductor wafer W is introduced into the chamber 11 to be heated to a predetermined temperature by means of the heater 14, and gases are supplied on the same conditions as those in the pre-coat process to carry out a deposition process of a Ti thin-film for a predetermined period of time. The deposition process of the Ti thin-film is carried out at a temperature of, e.g., about 400 to 1000° C.

After a constant number of the semiconductor wafers W are treated in the deposition process and are discharged from the chamber 11, ClF₃ gas serving as a cleaning gas is introduced into the chamber 11 to clean the interior of the chamber 11.

In such a system, the top-stage block body 20a and middle-stage block body 20b of the shower head 20 are made of an Ni alloy (Hastelloy C22), and the bottom-stage block body 20c of the shower head 20 is made of pure Ni (normal carbon (NC)-Ni). When a new shower head, a shower head, the surface of which has been chemically cleaned (chemically polished), mechanically polished or processed, or a shower head, the surface of which has been used in a deposition process to be processed, there is a problem in that a thin-film is peeled of f from the surface of the shower head (the bottom surface of the bottom-stage block body 20c) during the pre-coat process.

In order to examine the cause of the peeling of the thin-film, the corrosion tests for the above described NC-Ni and C22 serving as materials of the shower head were carried out. Since corrosive gases are TiCl₄and ClF₃ gases in the Ti-CVD process, the corrosion tests due to TiCl₄ and ClF₃ gases are alternately twice, respectively.

Experimental conditions are as follows.

(1) TiCl₄

Flow Rate of Ar: 0.090 m³/sec (1500 sccm)

Flow Rate of TiCl₄: 0.003 m³/sec (50 sccm)

Pressure: 733.2 Pa (5.5 Torr)

Time: 400 min

Temperature: 500° C. (Heater Setting Temperature)

(2) ClF₃

Flow Rate of Ar: 0.030 m³/sec (500 sccm)

Flow Rate of TiCl₄: 0.003 m³/sec (50 sccm)

Pressure: 173.3 Pa (1.3 Torr)

Time: 62 min

Temperature: 200° C. (Heater Setting Temperature)

The surface state was observed by a SEM. As a result, in the case of NC-Ni, a crystalline deposition was observed on the surface by the first TiCl₄ process. Although the surface state was deteriorated by the next ClF₃ process, no deposition was observed after the second TiCl₄ process. On the other hand, in the case of C22, the same crystalline deposition as that in the case of NC-Ni was observed by the first TiCl₄ process. Although the deterioration of the surface state such as Ni did not appear, it was confirmed that a thin-film-like material was cracked on the surface. After the second TiCl₄ process, the peeling of the thin-film was not observed although the deposition remained.

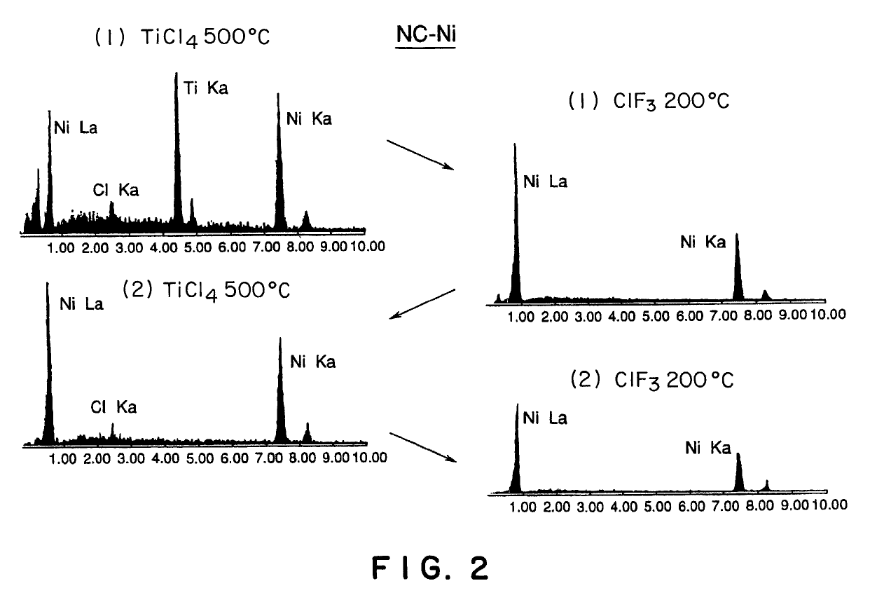

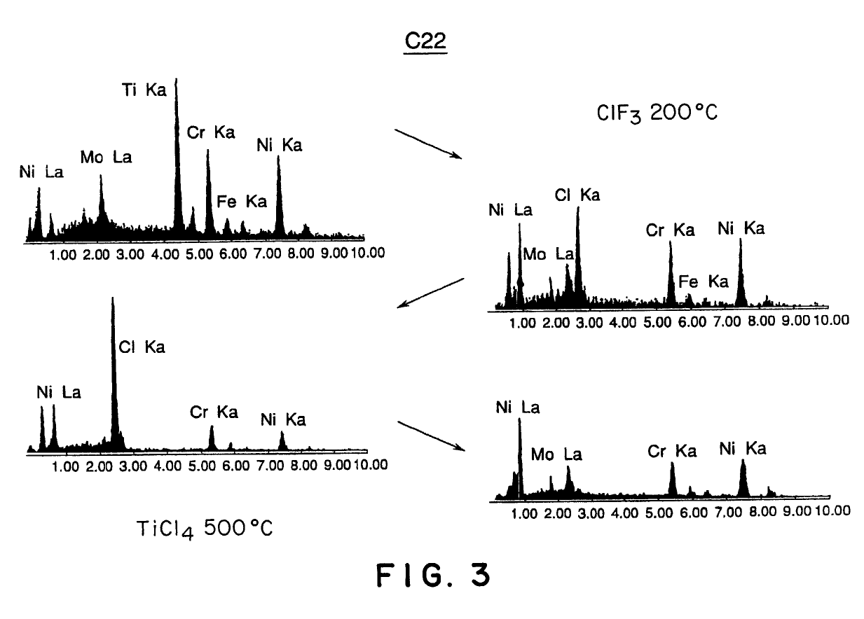

Then, EDAX (Energy-Dispersion Analysis of X-ray) measurements were carried out with respect to samples after the respective processes. Their measurement profiles are shown in FIGS. 2 and 3.

FIG. 2 shows the results for NC-Ni. In the sample after the first TiCl₄ process, Ti and Cl, together with Ni, were detected. In the sample after the next ClF₃ process, Ti was not detected, and in the second TiCl₄ process, Ti was also not detected. That is, Ti was completely removed by the ClF₃ process, and Ti was not deposited in the second TiCl₄ process.

On the other hand, FIG. 3 shows the results for C22. In the sample after the first TiCl₄ process, Ti, together with Ni and alloying element, was detected. However, similar to the case of NC-Ni shown in FIG. 2, Ti was not detected in the sample after the next ClF₃ process, and Ti was also detected after the second TiCl₄ process.

Then, with respect to samples after the respective processes, XRD (X-ray diffraction) measurements were carried out. As a result, in the case of NC-Ni, in the sample after the first TiCl₄process, NiTi was identified. By the next ClF₃process, NiTi was not identified, and NiF₃was identified. On the other hand, in the case of C22, only a face centered cubic (fcc) crystal alloy was identified after each of the processes.

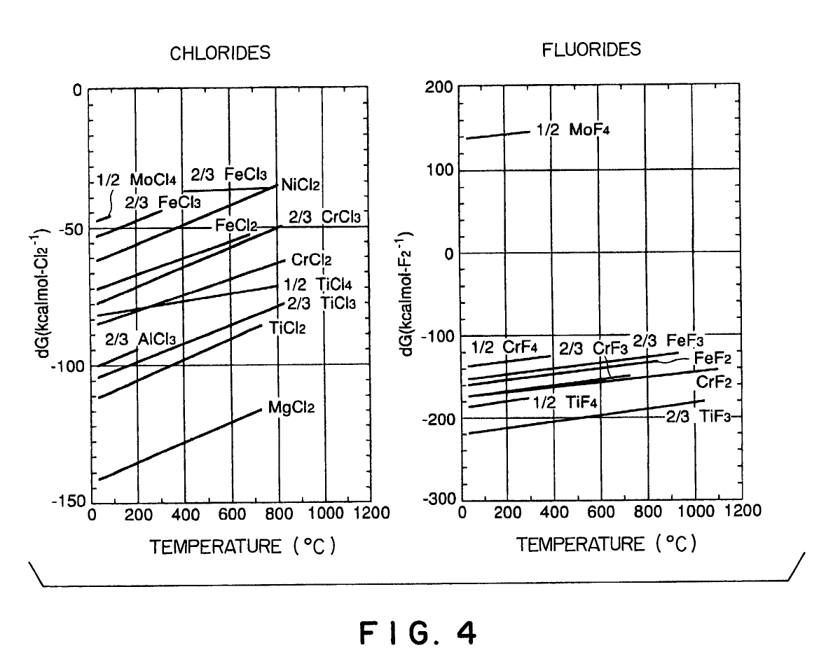

As shown in FIG. 4, Gibbs free energies of chlorides and fluorides which may be produced in these reaction systems are expressed at 500° C. as follows.

ΔG (TiClₓ)<ΔG (CrCl₂), ΔG (NiC₂)

ΔG (TiFₓ)<ΔG (CrFₓ)

Under the atmosphere of Cl, Ti is more easily chloridized than Cr or Ni, so that TiClx tends to be deposited. Similarly, under the atmosphere of F, equilibrium moves so as to fluoridize Ti. However, TiFₓ is vaporized and is not deposited since its vapor pressure is high.

From the above results, it is considered that the following reaction formulae are established in the first TiCl₄ process, the ClF₃ process and the second TiCl₄ process.

(1) Pure Ni (NC-Ni)

(First TiCl₄ Process)

Ni+TiCl₄→NiTi+NiClₓ↑+TiCLₓ↑

(ClF₃ Process)

NiTi+TiClx+ClF₃ →TiFₓ↑+NiFₓ (PF)+Cl₂ ↑

(Second TiCl₄ Process)

NiFx+TiCl₄ →NiClₓ↑+TiFₓ↑

(2) Hastelloy (C22)

(First TiCl₄ Process)

Ni+Cr+TiCl₄ →NiClₓ↑+CrClₓ (PF)+TiCLₓ↑

(ClF₃ Process)

Ni+CrClₓ+ClF₃ →NiFₓ (PF)+CrFₓ↑+Cl₃ ↑

(Second TiCl₄ Process)

NiFₓ++Cr+TiCl₄ →NiClₓ↑+CrClₓ (PF)+TiFₓ↑

(in the above formulae, PF denotes a passivation film)

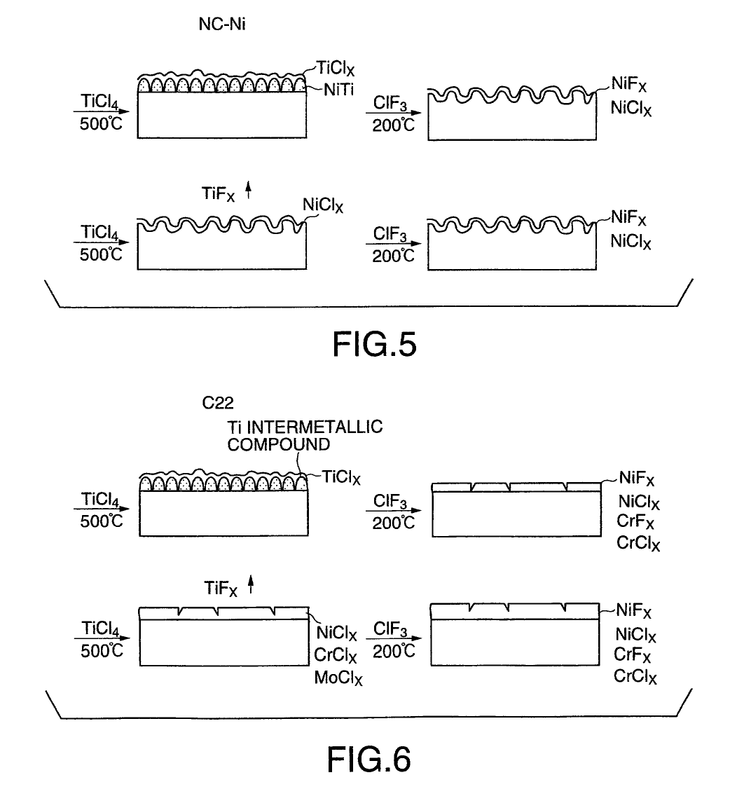

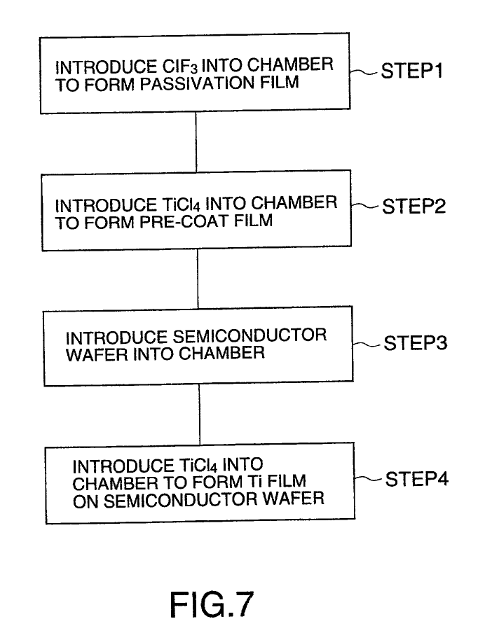

The states of such reactions are schematically shown in FIGS. 5 and 6. FIG. 5 shows the case of NC-Ni, and FIG. 6 shows the case of C22. Thus, in either case of NC-Ni or C22, although TiClₓ which is easily peeled off is formed on the surface when the first TiCl₄ process is carried out, an NiFₓ passivation film is formed without forming TiClₓ if the ClF₃ process is carried out. Thereafter, films which are easily peeled off, such as TiClₓ, are no more formed even though the TiCl₄ process is carried out again, because the NiFₓ has been formed and gaseous material of NiClₓ, TiFₓ and CrFₓ and so forth are generated. Such the gaseous material of NiClₓ, TiFₓ and CrFₓ are finally discharged from the chamber 11 without forming a film which might be easily peeled off.

In view of the foregoing, according to the present invention, in order to deposit a CVD-Ti thin-film using, e.g., the CVD-Ti deposition system of FIG. 1, if a new shower head or a chemically cleaned shower head is introduced as the shower head 20, ClF₃ gas is first introduced into the chamber 11 from the ClF₃ source 33, and subsequently, an NiFₓ passivation film is formed on the surface of the shower head 20 in situ (while maintaining the previous state without changing the state in the chamber 11 and so forth) (STEP 1). Thereafter, the supply of ClF₃ gas is stopped, and while TiCl₄ is introduced into the chamber 11 from the TiCl₄ source 31, a high-frequency power is applied to the shower head 20 from the high-frequency power supply 43 to produce the plasma of the gases to form a pre-coat film (STEP 2). Thereafter, a semiconductor wafer W is introduced into the chamber (STEP 3), and the wafer is heated to a predetermined temperature by means of the heater 14 to carry out a deposition process while passing TiCl₄ on the same conditions as those in the pre-coat process (STEP 4). By thus carrying out the passivation process using ClF₃ gas, TiClₓ is not produced in the pre-coat process at STEP 2 as described above, so that the films are not difficult to be peeled off during the pre-coat process even of the new shower head or the like is used.

In the deposition system of FIG. 1, such a passivation process has only to be carried out in situ after ClF₃ gas serving as the cleaning gas is introduced into the chamber from the cleaning gas supply system which is originally provided in the CVD system, so that it is possible to very easily and inexpensively form the passivation film.

The above described passivation using ClF₃ gas can be carried out on, e.g., the following conditions.

Flow Rate of ClF₃ Gas: 0.003˜0.030 m³/sec (50˜500 sccm)

Flow Rate of Ar Gas: 0.006˜0.060 m³/sec (100˜1000 sccm)

Flow Rate of N₂ Gas: 0.003˜0.030 m³/sec (50˜500 sccm)

Flow Rate of Ar Gas (Purge Gas): 0.003 m³/sec (50 sccm)

Pressure: 0.67×10²˜6.65×10² Pa (0.5˜5 Torr)

Temperature: 150˜500° C.

Time: 100˜2000 sec

Preferred conditions in the above described ranges are shown below.

Flow Rate of ClF₃ Gas: 0.012 m³/sec (200 sccm)

Flow Rate of Ar Gas: 0.024 m³/sec (400 sccm)

Flow Rate of N₂ Gas: 0.006 m³/sec (100 sccm)

Flow Rate of Ar Gas (Purge Gas): 0.003 m³/sec (50 sccm)

Pressure: 1.60×10²˜4.00×10² Pa (1.2˜3 Torr)

Temperature: 200° C.

Time: 1000 sec

As the above described example, the first passivation film forming process preferably uses ClF₃ gas serving as a cleaning gas, but it may use any one of other fluorine containing gases if a passivation film of an effective metal fluoride can be formed. For example, the other fluorine containing gas include NF₃, HF, F₂, C₂F₆ and C₄F₈.

The material should not be limited to the above described Ni or Ni alloy, but it may be a material capable of forming a passivation film of a metal fluoride such as NiFₓ, e.g., a metal or alloy containing at least one of Al, Fe, Cr, Cu and Ag. Using Al as an example, an AlFₓ passivation film can be formed by the reaction with ClF₃. If an effective passivation film can be formed, the material may be a ceramic material such as alumina. In addition, a coating film, e.g., a plated film, a thermal spray film, a CVD film, or a PVD film formed by sputtering or the like, which is made of any one of the above described materials, may be formed on the surface of a matrix.

There is not only the possibility that films may be peeled off from the shower head, but there is also the possibility that films may be similarly peeled off from other members existing in the chamber, e.g., the guide ring and the inner wall of the chamber. Therefore, such an in-situ passivation is effectively carried out with respect to all of members in the CVD system and the inner wall of the chamber. For example, the chamber is usually formed of Al, it is possible to effectively prevent films from being peeled off by forming an AlFₓ passivation film.

While the deposition of the Ti film using TiCl₄ as the deposition gas has been described as an example, it is possible to prevent easily peeled compounds from being produced in the case of an organic Ti compound by carrying out a passivation process using a fluorine containing gas such as ClF₃ and thereafter by allowing Ti to react with F to vaporize the reactant during the subsequent deposition process. By the same principle, the present invention may be applied to a case where there are used deposition gases such as chlorides or organic metal compounds, which are used for forming thin-films of other materials such as Si, Al and Cu, e.g., DMAH, Cu(hfac)₂, Cu(hfa)vtms, Ta(OC₂H₅)₅, SiCl₄ or WCL₄. The material of the passivation film should not be limited to the metal fluoride, but it may be any one of other compounds such as metal chlorides. The gases for passivation should not be limited to fluorine containing gases.

In order to carry out the present invention, the structure of the deposition system should not be limited to the above described structure, but the deposition system may be any one of CVD systems. For example, while the above described system has used the matrix type shower head, the present invention should not be limited thereto. The high-frequency power supply has only to be used if necessary, and is not always required in some kind of deposition reaction. The substrates to be used should not be limited to semiconductor wafers, but the substrates may be other wafers or substrates on the surface of which other layers are formed.

As described above, according to the present invention, it is possible to form a desired passivation film, which prevents films from being peeled off during a pre-coat process, on the inner wall of the chamber and/or the surfaces of the members in the chamber, with a simple method for introducing a passivating gas into the chamber in which an object to be processed does not exist. Therefore, it is possible to effectively and inexpensively prevent films from being peeled off from the inner wall of the chamber and the members in the chamber.

For example, when a passivation film of a fluoride is formed on the inner wall of the chamber and/or the surfaces of the members in the chamber by supplying a fluorine containing gas into the chamber, even if the passivation film of the fluoride reacts with a deposition gas which will be subsequently supplied, reaction products can be discharged as gaseous components, and it is possible to prevent films from being peeled off, so that it is possible to prevent peeled films from having a bad influence on the process.

If the CVD system has a cleaning gas supply system for supplying a fluorine containing gas, e.g., ClF₃, as a cleaning gas, the cleaning gas has only to be introduced from the cleaning gas supply system, which is originally provided in the CVD system, into the chamber at a predetermined temperature, so that it is possible to very easily form a passivation film on the inner wall of the chamber and/or the surfaces of the members in the chamber.

While the present invention has been disclosed in terms of the preferred embodiment in order to facilitate better understanding thereof, it should be appreciated that the invention can be embodied in various ways without departing from the principle of the invention. Therefore, the invention should be understood to include all possible embodiments and modification to the shown embodiments which can be embodied without departing from the principle of the invention as set forth in the appended claims.

What is claimed is:

1. A chemical vapor deposition method comprising the steps of:
supplying a passivating gas into a chamber, in which a chemical vapor deposition is carried out, while no object to be processed exists in the chamber, to form a passivation film on at least one of the inner wall of the chamber and the surface of a member in the chamber;
subsequently to said step of forming said passivation film, supplying a pre-coating gas into said chamber while no object to be processed exists in said chamber, to form a pre-coat film on the surface of said passivation film;
introducing an object to be processed, into said chamber; and
supplying a depositing gas into said chamber to carry out a deposition process on said object.

2. A chemical vapor deposition method comprising the steps of:
supplying a passivating gas into a chamber, in which a chemical vapor deposition is carried out, while no object to be processed exists in the chamber, to form a passivation film on at least one of the inner wall of the chamber and the surface of a member in the chamber;
subsequently to said step of forming said passivation film, supplying a pre-coating gas into said chamber while no object to be processed exists in said chamber, and producing a first plasma, to form a pre-coat film on the surface of said passivation film;
introducing an object to be processed, into said chamber; and
supplying a depositing gas into said chamber and producing a second plasma to carry out a deposition process on said object.

3. A chemical vapor deposition method as set forth in claim 1 or 2, wherein said passivation film contains at least one of a metal fluoride and a metal chloride.

4. A chemical vapor deposition method as set forth in claim 3, wherein said passivating gas contains a fluorine containing gas.

5. A chemical vapor deposition method as set forth in claim 4, wherein said fluorine containing gas contained in said passivating gas is ClF₃, NF₃, HF, F₂, C₂F₆ or C₄F₈.

6. A chemical vapor deposition method as set forth in any one of claims 1 through 5, wherein said pre-coating gas and said depositing gas contain a metal chloride, an organic metal compound and a reducing gas and a innert gas.

7. A chemical vapor deposition method comprising the steps of:
supplying a fluorine containing gas into a chamber, in which a chemical vapor deposition is carried out, while no object to be processed exists in the chamber, to previously form a passivation film of a metal fluoride on at least one of the inner wall of the chamber and the surface of a member in the chamber;
subsequently to said step of forming said passivation film, supplying a depositing gas into said chamber while no object to be processed exists in said chamber, to form a pre-coat film on the surface of said passivation film;
introducing an object to be processed, into said chamber; and
supplying a depositing gas into said chamber to carry out a deposition process on said object.

8. A chemical vapor deposition method comprising the steps of:
supplying a fluorine containing gas into a chamber, in which a chemical vapor deposition is carried out, while no object to be processed exists in the chamber, to previously form a passivation film of a metal fluoride on at least one of the inner wall of the chamber and the surface of a member in the chamber;
subsequently to said step of forming said passivation film, supplying a depositing gas into said chamber while no object to be processed exists in said chamber, and producing a first plasma, to form a pre-coat film on the surface of said passivation film;
introducing an object to be processed, into said chamber; and
supplying a depositing gas into said chamber and producing a second plasma to carry out a deposition process on said object.

9. A chemical vapor deposition method for carrying out a deposition process using a chemical vapor deposition system comprising a chamber for carrying out a chemical vapor deposition, a deposition gas supply system for supplying a deposition gas into said chamber, and a cleaning gas supply system for supplying a fluorine containing gas into said chamber as a cleaning gas for cleaning after deposition, said method comprising the steps of:
supplying said fluorine containing gas serving as said cleaning gas into said chamber while no object to be processed exists in said chamber, to form a passivation film of a metal fluoride on at least one of the inner wall of said chamber and the surface of a member in said chamber;
subsequently to said step of forming said passivation film, supplying a depositing gas from said deposition gas supply system into said chamber while no object to be processed exists in said chamber, to form a pre-coat film on the surface of said passivation film;
introducing an object to be processed, into said chamber; and
supplying a depositing gas from said deposition gas supply system into said chamber to carry out a deposition process on said object.

10. A chemical vapor deposition method as set forth in any one of claims 7 through 9, wherein said fluorine containing gas is ClF₃, NF₃, HF, F₂, C₂F₆, or C₄F₈.

11. A chemical vapor deposition method as set forth in any one of claims 7 through 10, wherein said depositing gas contains a metal chloride, an organic metal compound and a reducing gas, and innert gas.

12. A chemical vapor deposition method as set forth in any one of claims 1 through 11, wherein said at least one of the inner wall of said chamber and the surface of the member in said chamber, on which said passivation film is formed, is formed of a metal containing material or a ceramic material.

13. A chemical vapor deposition method as set forth in claim 12, wherein said metal containing material is a metal or alloy containing at least one of Al, Ni, Fe, Cr, Cu and Ag.

14. A chemical vapor deposition method as set forth in claim 12 or 13, wherein a coating film is formed on said at least one of the inner wall of said chamber and the surface of the member in said chamber.
